(19) United States
(12) Patent Application Publication
(10) Pub. No.: US 2025/0053088 A1
(43) Pub. Date: Feb. 13, 2025

(54) COMPOSITION FOR FORMING RESIST UNDERLAYER FILM HAVING SACCHARIN SKELETON

(71) Applicant: NISSAN CHEMICAL CORPORATION, Tokyo (JP)

(72) Inventors: Tomotada HIROHARA, Toyama-shi (JP); Mamoru TAMURA, Toyama-shi (JP)

(73) Assignee: NISSAN CHEMICAL CORPORATION, Tokyo (JP)

(21) Appl. No.: 18/718,710

(22) PCT Filed: Dec. 22, 2022
(86) PCT No.: PCT/JP2022/047257

§ 371 Date: Jun. 11, 2024

(30) Foreign Application Priority Data
Dec. 24, 2021 (JP) 2021-210529

(51) Int. Cl. G03F 7/039; C08L 63/04; G03F 7/004; G03F 7/20; G03F 7/32

(52) U.S. Cl. CPC G03F 7/0395; C08L 63/04; G03F 7/0048; G03F 7/2004; G03F 7/322

(57) ABSTRACT

A composition for forming a resist underlayer film, containing a solvent and a polymer including a structure represented by formula (A) below.

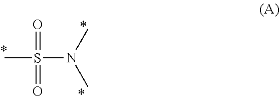

In formula (A), * represents a bond.

### TECHNICAL FIELD

The present invention relates to a composition for forming a resist underlayer film, a resist underlayer film, a substrate for semiconductor processing, a method for producing a semiconductor element, a method for forming a pattern, and a polymer that can be suitably used for the composition for forming a resist underlayer film.

### BACKGROUND ART

Conventionally, microfabrication by lithography using a resist composition has been performed in the production of a semiconductor device. The microfabrication is a processing method of forming microrelief corresponding to a photoresist pattern on a substrate surface by forming a thin film of a photoresist composition on a semiconductor substrate such as a silicon wafer, irradiating the thin film with an active ray such as an ultraviolet ray through a mask pattern on which a device pattern is drawn, developing the thin film, and etching the substrate using the obtained photoresist pattern as a protective film. In recent years, the degree of integration of semiconductor devices has been increased, and also as the active ray to be used, in addition to i-line (wavelength: 365 nm), KrF excimer laser (wavelength: 248 nm), and ArF excimer laser (wavelength: 193 nm) that have been conventionally used, practical application of EUV light (wavelength: 13.5 nm) or an electron beam (EB) has been studied for the most advanced microfabrication. Along with this, poor resist pattern formation due to an influence of a semiconductor substrate or the like becomes a major problem. Therefore, in order to solve this problem, a method of providing a resist underlayer film between a resist and a semiconductor substrate has been widely studied.

Patent Literature 1 discloses a composition for forming a underlayer film for lithography containing a naphthalene ring having a halogen atom. Patent Literature 2 discloses a halogenated antireflection film. Patent Literature 3 discloses a composition for forming a resist underlayer film.

### CITATION LIST

### Patent Literature

Patent Literature 1: WO 2006/003850 A
Patent Literature 2: JP 2005-526270 A
Patent Literature 3: WO 2020/111068 A

### SUMMARY OF INVENTION

### Technical Problem

In a negative development process in which an unexposed portion of a resist film is removed using a solvent (usually an organic solvent) capable of dissolving the resist film and an exposed portion of the resist film is left as a resist pattern or a positive development process in which an exposed portion of the resist film is removed and an unexposed portion of the resist film is left as a resist pattern in a development step at the time of forming the resist pattern, improvement of adhesion of the resist pattern to a base is a major problem. This is because when the adhesion between the resist pattern and a base is low, the pattern tends to collapse when a fine resist pattern is to be formed, and as a result, it becomes difficult to form a fine resist pattern.

An object of the present invention is to provide a composition for forming a resist underlayer film for forming a resist underlayer film capable of forming a fine resist pattern by preventing pattern collapse of the resist pattern.

Another object of the present invention is to provide a resist underlayer film obtained from the composition for forming a resist underlayer film, a substrate for semiconductor processing using the resist underlayer film, a method for producing a semiconductor element using the composition for forming a resist underlayer film, and a method for forming a pattern.

In addition, an object of the present invention is to provide a polymer that can be suitably used for a composition for forming a resist underlayer film.

### Solution to Problem

As a result of intensive studies to solve the above-mentioned problems, the present inventors found that the above-mentioned problems can be solved, and completed the present invention having the following gist.

That is, the present invention includes the following aspects.

[1] A composition for forming a resist underlayer film, containing a solvent and a polymer including a structure represented by formula (A) below.

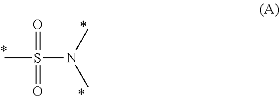

In formula (A), * represents a bond.

[2] The composition for forming a resist underlayer film according to [1], wherein the polymer has a structure represented by formula (A) in a side chain.

[3] The composition for forming a resist underlayer film according to [1] or [2], wherein the polymer has a structure represented by formula (A) in a unit structure.

[4] The composition for forming a resist underlayer film according to any one of [1] to [3], wherein the polymer has, in a side chain, a structure represented by formula (A-1) below as a structure including the structure represented by formula (A).

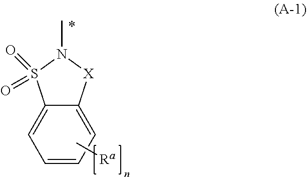

In formula (A-1), X represents —CO— or —SO₂—,
R^{a} represents a halogen atom, an alkyl group having 1 to 8 carbon atoms, which may have a substituent, an alkoxy group having 1 to 8 carbon atoms, which may have a substituent, an alkylthio group having 1 to 5 carbon atoms, a nitro group, or a cyano group,
n represents an integer of 0 to 4,
when there are two or more R^{a}'s, two or more R^{a}'s may be identical or different, and
* represents a bond.

[5] The composition for forming a resist underlayer film according to [4], wherein the polymer has a unit structure represented by formula (1) below as a unit structure including the structure represented by formula (A-1).

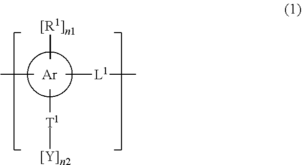

In formula (1), Ar represents a benzene ring, a naphthalene ring, or an anthracene ring,
R¹ represents a hydroxy group, a mercapto group which may be protected by a methyl group, an amino group which may be protected by a methyl group, a halogen atom, or an alkyl group having 1 to 10 carbon atoms, which may be substituted or interrupted by a hetero atom or may be substituted by a hydroxy group,
n1 represents an integer of 0 to 3,
n2 represents 1 or 2,
L¹ represents a single bond or an alkylene group having 1 to 10 carbon atoms,
Y represents a group represented by formula (A-2) below,
T¹ represents a single bond, an ether bond, an ester bond, or an amide bond (—NHCO—) when n2 is 1, and
T¹ represents a nitrogen atom or an amide bond when n2 is 2.

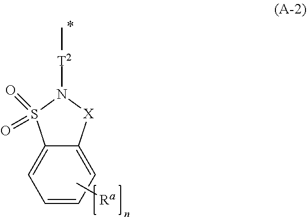

In formula (A-2), T² represents a divalent organic group having 1 to 10 carbon atoms,
X represents —CO— or —SO₂—,
R^{a} represents a halogen atom, an alkyl group having 1 to 8 carbon atoms, which may have a substituent, an alkoxy group having 1 to 8 carbon atoms, which may have a substituent, an alkylthio group having 1 to 5 carbon atoms, a nitro group, or a cyano group,
n represents an integer of 0 to 4,
when there are two or more R^{a}'s, two or more R^{a}'s may be identical or different, and
* represents a bond.

[6] The composition for forming a resist underlayer film according to any one of [1] to [5], further containing a crosslinking agent.

[7] The composition for forming a resist underlayer film according to any one of [1] to [6], further containing a curing catalyst.

[8] A resist underlayer film which is a cured product of the composition for forming a resist underlayer film according to any one of [1] to [7].

[9] A substrate for semiconductor processing including:
a semiconductor substrate; and
the resist underlayer film according to [8].

[10] A method for producing a semiconductor element, the method including steps of:
forming a resist underlayer film using the composition for forming a resist underlayer film according to any one of [1] to [7]; and
forming a resist film on the resist underlayer film using a resist.

[11] A method for forming a pattern, the method including steps of:
forming a resist underlayer film using the composition for forming a resist underlayer film according to any one of [1] to [7];
forming a resist film on the resist underlayer film using a resist;
irradiating the resist film with light or an electron beam, and then developing the resist film to obtain a resist pattern; and
etching the resist underlayer film using the resist pattern as a mask.

[12] A polymer having a unit structure represented by formula (1) below.

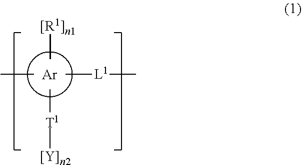

In formula (1), Ar represents a benzene ring, a naphthalene ring, or an anthracene ring,
R¹ represents a hydroxy group, a mercapto group which may be protected by a methyl group, an amino group which may be protected by a methyl group, a halogen atom, or an alkyl group having 1 to 10 carbon atoms, which may be substituted or interrupted by a hetero atom or may be substituted by a hydroxy group,
n1 represents an integer of 0 to 3,
n2 represents 1 or 2,
L¹ represents a single bond or an alkylene group having 1 to 10 carbon atoms,
Y represents a group represented by formula (A-2) below,
T¹ represents a single bond, an ether bond, an ester bond, or an amide bond (—NHCO—) when n2 is 1, and
T¹ represents a nitrogen atom or an amide bond when n2 is 2.

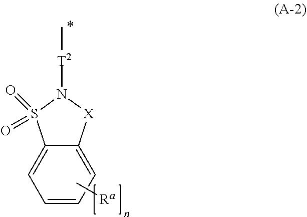

In formula (A-2), T² represents a divalent organic group having 1 to 10 carbon atoms,
X represents —CO— or —SO₂—,
R^{a} represents a halogen atom, an alkyl group having 1 to 8 carbon atoms, which may have a substituent, an alkoxy group having 1 to 8 carbon atoms, which may have a substituent, an alkylthio group having 1 to 5 carbon atoms, a nitro group, or a cyano group,
n represents an integer of 0 to 4,
when there are two or more R^{a}'s, two or more R^{a}'s may be identical or different, and
* represents a bond.

### Advantageous Effects of Invention

According to the present invention, it is possible to provide a composition for forming a resist underlayer film for forming a resist underlayer film capable of forming a fine resist pattern by preventing pattern collapse of the resist pattern.

In addition, according to the present invention, it is possible to provide a resist underlayer film obtained from the composition for forming a resist underlayer film, a substrate for semiconductor processing using the resist underlayer film, a method for producing a semiconductor element using the composition for forming a resist underlayer film, and a method for forming a pattern.

Further, according to the present invention, it is possible to provide a polymer that can be suitably used for a composition for forming a resist underlayer film.

### DESCRIPTION OF EMBODIMENTS

### (Composition for Forming Resist Underlayer Film)

The composition for forming a resist underlayer film of the present invention contains a polymer and a solvent.

### <Polymer>

The polymer includes a structure represented by formula (A) below.

The polymer is also a subject of the present invention.

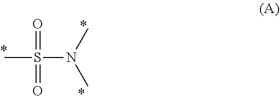

In formula (A), * represents a bond.

In the present invention, the structure represented by formula (A) or a structure represented by formula (A-1) below is referred to as a saccharin skeleton.

When the polymer includes the structure represented by formula (A), adhesion between the resist pattern and the resist underlayer film can be improved. As a result, a fine resist pattern can be formed.

The polymer may have the structure represented by formula (A) in a main chain or in a side chain, but preferably in a side chain from the viewpoint of suitably obtaining the effect of the present invention.

The polymer has, for example, the structure represented by formula (A) in a unit structure.

The polymer preferably has a structure represented by formula (A-1) below as a structure including the structure represented by formula (A) in a side chain from the viewpoint of suitably obtaining the effect of the present invention.

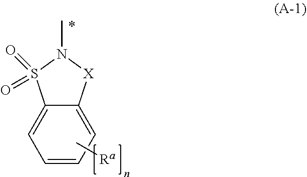

In formula (A-1), X represents —CO— or —SO₂—,

R^{a} represents a halogen atom, an alkyl group having 1 to 8 carbon atoms, which may have a substituent, an alkoxy group having 1 to 8 carbon atoms, which may have a substituent, an alkylthio group having 1 to 5 carbon atoms, a nitro group, or a cyano group,
n represents an integer of 0 to 4,
when there are two or more R^{a}'s, two or more R^{a}'s may be identical or different, and
* represents a bond.

The polymer may have one kind or two or more kinds of structures represented by formula (A-1).

### <<R^{a}>>

In the present description, examples of the halogen atom include a fluorine atom, a chlorine atom, a bromine atom, and an iodine atom.

The number of carbon atoms in the alkyl group in the alkyl group having 1 to 8 carbon atoms, which may have a substituent, may be 1 to 6 or 1 to 4.

Examples of the alkyl group in the alkyl group having 1 to 8 carbon atoms, which may have a substituent, include a methyl group, an ethyl group, a n-propyl group, an i-propyl group, a cyclopropyl group, a n-butyl group, an i-butyl group, a s-butyl group, a t-butyl group, a cyclobutyl group, a 1-methyl-cyclopropyl group, a 2-methyl-cyclopropyl group, a n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group.

The number of carbon atoms in the alkoxy group in the alkoxy group having 1 to 8 carbon atoms, which may have a substituent, may be 1 to 6 or 1 to 4.

Examples of the alkoxy group in the alkoxy group having 1 to 8 carbon atoms, which may have a substituent, include a methoxy group, an ethoxy group, a n-propoxy group, an i-propoxy group, a n-butoxy group, an i-butoxy group, a s-butoxy group, a t-butoxy group, a n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, a n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, a 1-ethyl-2-methyl-n-propoxy group, a cyclopentyloxy group, and a cyclohexyloxy group.

Examples of the alkylthio group having 1 to 5 carbon atoms include a methylthio group, an ethylthio group, a propylthio group, a butylthio group, and a pentylthio group.

In the alkyl group having 1 to 8 carbon atoms, which may have a substituent, and the alkoxy group having 1 to 8 carbon atoms, which may have a substituent, the phrase “may have a substituent” means that some or all hydrogen atoms present in the alkyl group or the alkoxy group may be substituted by, for example, a hydroxy group, a halogen atom, a carboxyl group, a nitro group, a cyano group, a methylenedioxy group, an acetoxy group, a methylthio group, an amino group, or an alkoxy group having 1 to 6 carbon atoms.

The polymer preferably has a unit structure represented by formula (1) below as a unit structure including the structure represented by formula (A-1) from the viewpoint of suitably obtaining the effect of the present invention.

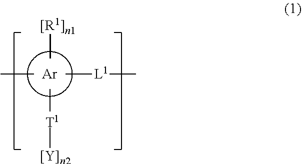

In formula (1), Ar represents a benzene ring, a naphthalene ring, or an anthracene ring,
R¹ represents a hydroxy group, a mercapto group which may be protected by a methyl group, an amino group which may be protected by a methyl group, a halogen atom, or an alkyl group having 1 to 10 carbon atoms, which may be substituted or interrupted by a hetero atom or may be substituted by a hydroxy group,
n1 represents an integer of 0 to 3,
n2 represents 1 or 2,
L¹ represents a single bond or an alkylene group having 1 to 10 carbon atoms,
Y represents a group represented by formula (A-2) below,
T¹ represents a single bond, an ether bond, an ester bond, or an amide bond (—NHCO—) when n2 is 1, and
T¹ represents a nitrogen atom or an amide bond when n2 is 2.

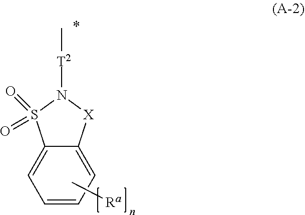

In formula (A-2), T² represents a divalent organic group having 1 to 10 carbon atoms,
X represents —CO— or —SO₂—,
R^{a} represents a halogen atom, an alkyl group having 1 to 8 carbon atoms, which may have a substituent, an alkoxy group having 1 to 8 carbon atoms, which may have a substituent, an alkylthio group having 1 to 5 carbon atoms, a nitro group, or a cyano group,
n represents an integer of 0 to 4,
when there are two or more R^{a}'s, two or more R^{a}'s may be identical or different, and
* represents a bond.

The polymer may have one kind or two or more kinds of unit structures represented by formula (1).

### <Ar>

Ar represents a benzene ring, a naphthalene ring, or an anthracene ring.

### <R¹>

R¹ represents, for example, a hydroxy group, a mercapto group which may be protected by a methyl group, an amino group which may be protected by a methyl group, or a halogen atom.

Examples of the amino group which may be protected by a methyl group include —NH₂, —N(CH₃)H, and —N(CH₃)₂.

R¹ may be an alkyl group having 1 to 10 carbon atoms, which may be substituted or interrupted by a hetero atom or may be substituted by a hydroxy group. Examples of the hetero atom include a halogen atom, a nitrogen atom, and an oxygen atom.

In the “alkyl group having 1 to 10 carbon atoms, which may be substituted or interrupted by a hetero atom or may be substituted by a hydroxy group”, examples of the alkyl group substituted by a hydroxy group include a hydroxyalkyl group. Examples of the alkyl group substituted or interrupted by an oxygen atom include an alkoxy group, an alkoxyalkyl group, an acyloxyalkyl group, and an alkoxycarbonylalkyl group.

Examples of the alkoxy group having 1 to 10 carbon atoms include a methoxy group, an ethoxy group, a n-propoxy group, an i-propoxy group, a n-butoxy group, an i-butoxy group, a s-butoxy group, a t-butoxy group, a n-pentoxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, a n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, a 1-ethyl-2-methyl-n-propoxy group, a n-heptyloxy group, a n-octyloxy group, and a n-nonyloxy group.

### <L¹>

L¹ represents a single bond or an alkylene group having 1 to 10 carbon atoms.

Examples of the alkylene group having 1 to 10 carbon atoms include a methylene group, an ethylene group, a 1,3-propylene group, a 1-methylethylene group, a 1,4-butylene group, a 1-ethylethylene group, a 1-methylpropylene group, a 2-methylpropylene group, a 1,5-pentylene group, a 1-methylbutylene group, a 2-methylbutylene group, a 1,1-dimethylpropylene group, a 1,2-dimethylpropylene group, a 1-ethylpropylene group, a 2-ethylpropylene group, a 1,6-hexylene group, a 1,4-cyclohexylene group, a 1,8-octylene group, a 2-ethyloctylene group, a 1,9-nonylene group, and a 1,10-decylene group.

L¹ is preferably a divalent group represented by formula (1-2) below.

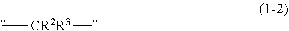

In formula (1-2), R² and R³ each independently represent a hydrogen atom, a methyl group, an ethyl group, a n-propyl group, an i-propyl group, a cyclopropyl group, a n-butyl group, an i-butyl group, a s-butyl group, a t-butyl group, or a cyclobutyl group,
R² and R³ may be bonded to each other to form a ring having 3 to 6 carbon atoms, and
* represents a bond.

Among them, both R² and R³ are preferably a hydrogen atom.

### <T¹>

T¹ represents a single bond, an ether bond, an ester bond, or an amide bond (—NHCO—) when n2 is 1.

T¹ represents a nitrogen atom or an amide bond when n2 is 2. This amide bond can also be represented by —N(−)CO—, and a nitrogen atom of the amide bond is not bonded to a hydrogen atom.

### <T²>

T² represents a divalent organic group having 1 to 10 carbon atoms. T² may have a hetero atom. Examples of the hetero atom include a halogen atom, an oxygen atom, and a nitrogen atom.

T² is preferably a group represented by formula (1-3) below.

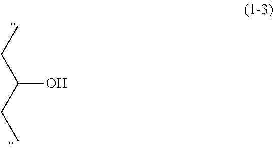

In formula (1-3), * represents a bond.

### <R^{a}>

Specific examples of R^{a} in formula (A-2) include specific examples of R^{a} in formula (A-1).

### <<Method for Producing Polymer>>

A method for producing the polymer including the structure represented by formula (A) is not particularly limited.

The polymer having a unit structure represented by formula (1) can be obtained, for example, by allowing a polymer having a unit structure represented by formula (1-1) below to react with a compound represented by formula (A-1-1) below.

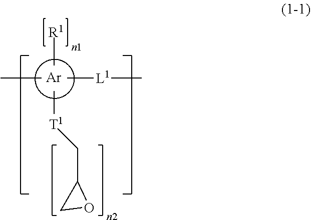

In formula (1-1), Ar represents a benzene ring, a naphthalene ring, or an anthracene ring,
R¹ represents a hydroxy group, a mercapto group which may be protected by a methyl group, an amino group which may be protected by a methyl group, a halogen atom, or an alkyl group having 1 to 10 carbon atoms, which may be substituted or interrupted by a hetero atom or may be substituted by a hydroxy group,
n1 represents an integer of 0 to 3,
n2 represents 1 or 2,
L¹ represents a single bond or an alkylene group having 1 to 10 carbon atoms,
T¹ represents a single bond, an ether bond, an ester bond, or an amide bond (—NHCO—) when n2 is 1, and
T¹ represents a nitrogen atom or an amide bond when n2 is 2.

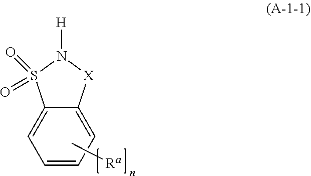

In formula (A-1-1), X represents —CO— or —SO₂—,
R^{a} represents a halogen atom, an alkyl group having 1 to 8 carbon atoms, which may have a substituent, an alkoxy group having 1 to 8 carbon atoms, which may have a substituent, an alkylthio group having 1 to 5 carbon atoms, a nitro group, or a cyano group,
n represents an integer of 0 to 4,
when there are two or more R^{a}'s, two or more R^{a}'s may be identical or different, and
* represents a bond.

Ar, R¹, L¹, T¹, n¹, and n2 in formula (1-1) have the same meanings as Ar, R¹, L¹, T¹, n¹, and n2 in formula (1), respectively.
X, R^{a}, and n in formula (A-1-1) have the same meanings as X, R^{a}, and n in formula (A-1) and formula (A-2), respectively.

Examples of the unit structure represented by formula (1-1) include unit structures below.

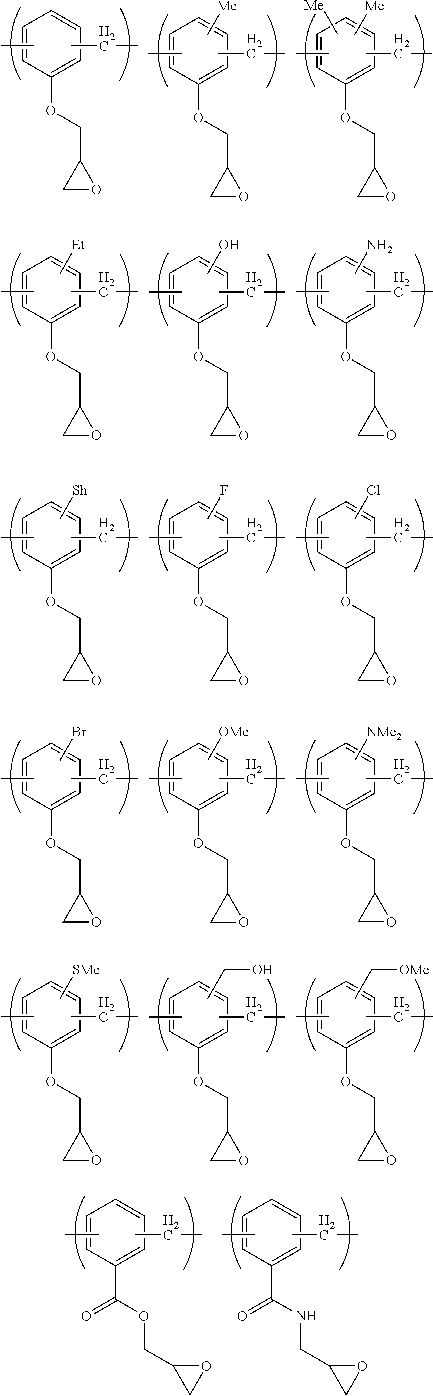

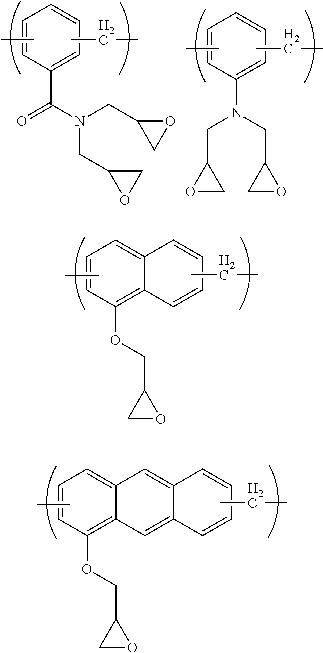

In the formulae, Me represents a methyl group, and Et represents an ethyl group.

The polymer including the structure represented by formula (A) may be a synthesized product or a commercially available product.

Examples of the commercially available product of the polymer having a unit structure represented by formula (1-1) include heat-resistant epoxy novolac resin EOCN (registered trademark) series (manufactured by Nippon Kayaku Co., Ltd.) and epoxy novolac resin D.E.N (registered trademark) series (manufactured by Dow Chemical Japan Co., Ltd.).

The compound represented by formula (A-1-1) may be a synthesized product or a commercially available product.

The compound represented by formula (A-1-1) is preferably o-sulfobenzimide (saccharin: in formula (A-1-1), X═—CO—, and n=0).

The molecular weight of the polymer is not particularly limited, but the weight average molecular weight by gel permeation chromatography is preferably 1,500 to 100,000, and more preferably 2,000 to 50,000.

The content of the polymer containing the structure represented by formula (A) in the composition for forming a resist underlayer film is not particularly limited, but is preferably 50 mass % to 100 mass %, more preferably 60 mass % to 99 mass %, and particularly preferably 70 mass % to 99 mass % with respect to the film-forming component.

The film-forming component is a component remaining in the resist underlayer film when the resist underlayer film is formed from the composition for forming a resist underlayer film. Examples of the film-forming component include a component present in the resist underlayer film as it is, a component present in the resist underlayer film as a reaction product with another component, and a component used as an auxiliary agent (for example, a curing catalyst) that assists a reaction of another component.

In other words, the film-forming component is a generic term for components other than the solvent among all the components of the composition for forming a resist underlayer film.

### <Crosslinking Agent>

The composition for forming a resist underlayer film preferably contains a crosslinking agent from the viewpoint of suitably obtaining the effect of the present invention.

The crosslinking agent contained as an optional component in the composition for forming a resist underlayer film has a functional group that reacts with itself.

Examples of the crosslinking agent include hexamethoxymethylmelamine, tetramethoxymethyl benzoguanamine, 1,3,4,6-tetrakis(methoxymethyl)glycoluril (tetramethoxymethyl glycoluril) (POWDERLINK [registered trademark]1174), 1,3,4,6-tetrakis(butoxymethyl)glycoluril, 1,3,4,6-tetrakis(hydroxymethyl)glycoluril, 1,3-bis (hydroxymethyl)urea, 1,1,3,3-tetrakis(butoxymethyl)urea, and 1,1,3,3-tetrakis(methoxymethyl)urea.

In addition, the crosslinking agent may be a nitrogen-containing compound having 2 to 6 substituents represented by formula (1d) below bonded to a nitrogen atom in one molecule described in WO 2017/187969 A.

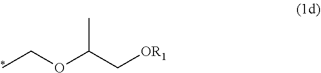

In formula (1d), R₁ represents a methyl group or an ethyl group, and * represents a bond bonded to a nitrogen atom.)

The nitrogen-containing compound having 2 to 6 substituents represented by formula (1d) in one molecule may be a glycoluril derivative represented by formula (1E) below.

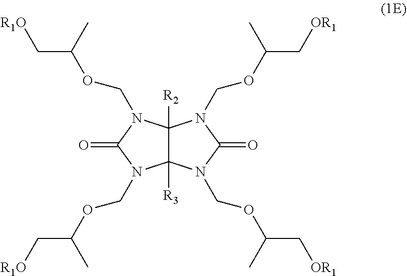

In formula (1E), four R₁'s each independently represent a methyl group or an ethyl group, and R₂ and R₃ each independently represent a hydrogen atom, an alkyl group having 1 to 4 carbon atoms, or a phenyl group.

Examples of the glycoluril derivative represented by formula (1E) include compounds represented by formula (1E-1) to formula (1E-6) below.

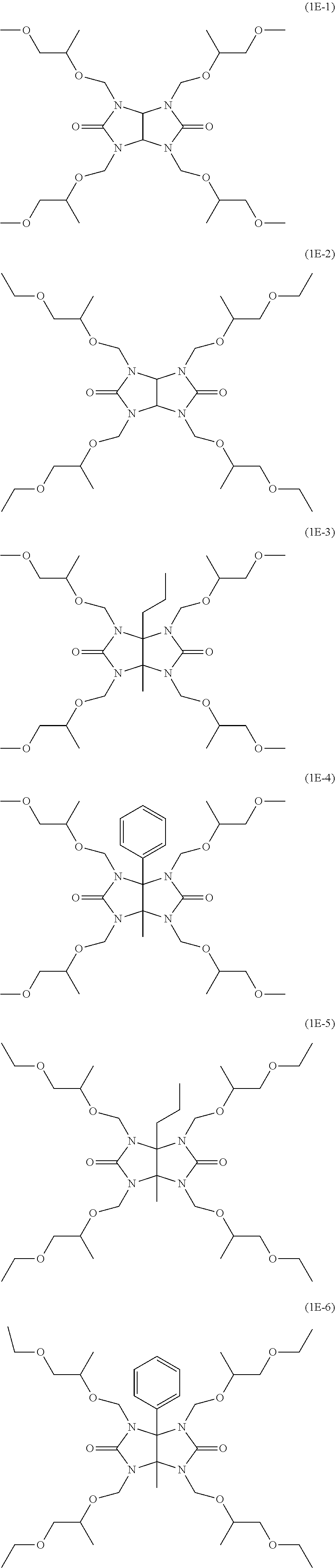

The nitrogen-containing compound having 2 to 6 substituents represented by formula (1d) in one molecule is obtained by allowing a nitrogen-containing compound having 2 to 6 substituents represented by formula (2d) below bonded to a nitrogen atom in one molecule to react with at least one compound represented by formula (3d) below.

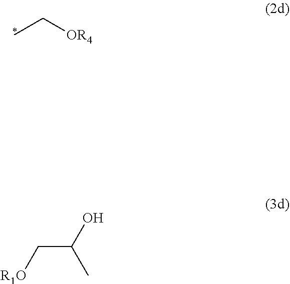

In formula (2d) and formula (3d), R₁ represents a methyl group or an ethyl group, R₄ represents an alkyl group having 1 to 4 carbon atoms, and * represents a bond bonded to a nitrogen atom.

The glycoluril derivative represented by formula (1E) is obtained by allowing a glycoluril derivative represented by formula (2E) below to react with at least one compound represented by formula (3d).

The nitrogen-containing compound having 2 to 6 substituents represented by formula (2d) in one molecule is a glycoluril derivative represented by formula (2E) below.

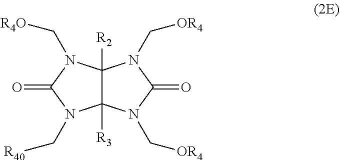

In formula (2E), R₂ and R₃ each independently represent a hydrogen atom, an alkyl group having 1 to 4 carbon atoms, or a phenyl group, and R₄'s each independently represent an alkyl group having 1 to 4 carbon atoms.

Examples of the glycoluril derivative represented by formula (2E) include compounds represented by formula (2E-1) to formula (2E-4) below. Further, examples of the compound represented by formula (3d) include compounds represented by formula (3d-1) and formula (3d-2) below.

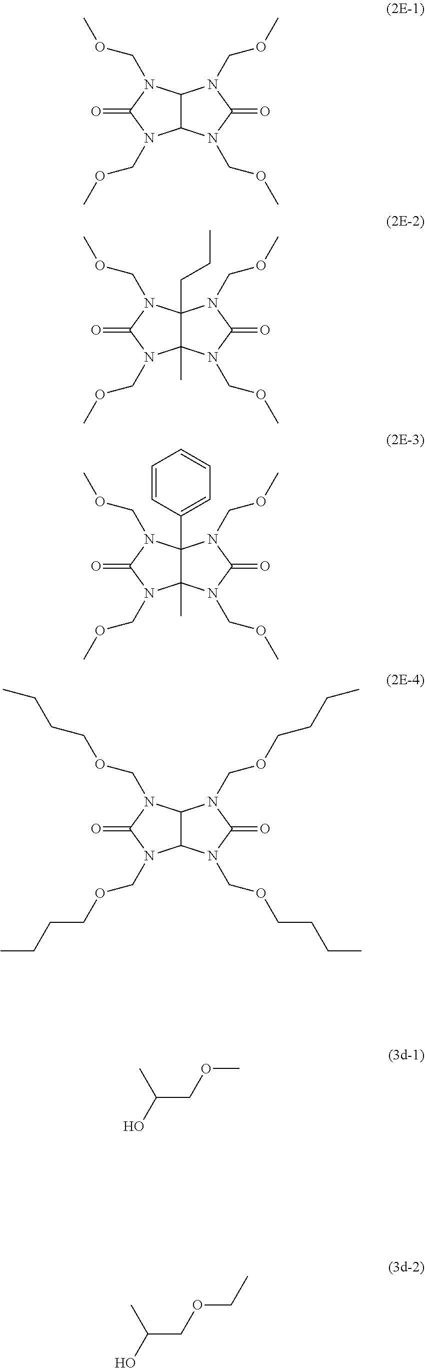

For the contents related to the nitrogen-containing compound having 2 to 6 substituents represented by formula (1d) bonded to a nitrogen atom in one molecule, the entire disclosure of WO 2017/187969 A is incorporated herein by reference.

Further, the crosslinking agent may be a crosslinkable compound represented by formula (G-1) or formula (G-2) below described in WO 2014/208542 A.

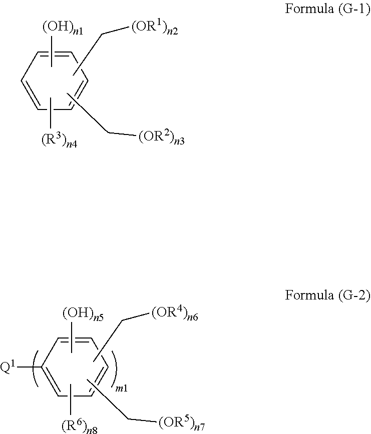

In the formulae, Q¹ represents a single bond or an m1-valent organic group, R¹ and R⁴ each represent an alkyl group having 2 to 10 carbon atoms or an alkyl group having 2 to 10 carbon atoms having an alkoxy group having 1 to 10 carbon atoms, R² and R⁵ each represent a hydrogen atom or a methyl group, R³ and R⁶ each represent an alkyl group having 1 to 10 carbon atoms or an aryl group having 6 to 40 carbon atoms, n1 represents an integer of 1≤n1≤3, n2 represents an integer of 2≤n2≤5, n3 represents an integer of 0≤n3≤3, and n4 represents an integer of 0≤n4≤3, satisfying 3≤(n1+n2+n3+n4)≤6, n5 represents an integer of 1≤n5≤3, and n6 represents an integer of 1≤n6≤4, n7 represents an integer of 0≤n7≤3, and n8 represents an integer of 0≤n8≤3, satisfying 2≤(n5+n6+n7+n8)≤5, and m1 represents an integer of 2 to 10.

The crosslinkable compound represented by formula (G-1) or formula (G-2) may be obtained by reaction of a compound represented by formula (G-3) or formula (G-4) below with a hydroxyl group-containing ether compound or an alcohol having 2 to 10 carbon atoms.

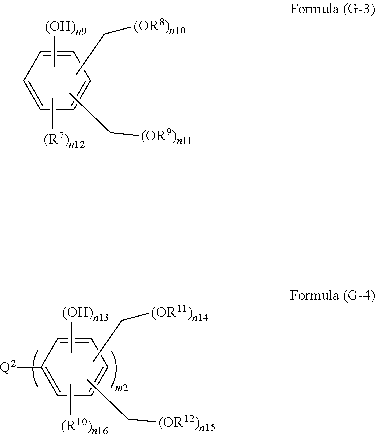

In the formulae, Q² represents a single bond or an m2-valent organic group, R⁸, R⁹, R¹¹, and R¹² each represent a hydrogen atom or a methyl group, R⁷ and R¹⁰ each represent an alkyl group having 1 to 10 carbon atoms or an aryl group having 6 to 40 carbon atoms, n9 represents an integer of 1≤n9≤3, n10 represents an integer of 2≤n10≤5, n11 represents an integer of 0≤n11≤3, and n12 represents an integer of 0≤n12≤3, satisfying 3≤(n9+n10+n11+n12)≤6, n13 represents an integer of 1≤n13≤3, n14 represents an integer of 1≤n14≤4, n15 represents an integer of 0≤n15≤3, and n16 represents an integer of 0≤n16≤3, satisfying 2≤(n13+n14+n15+n16)≤5, and m2 represents an integer of 2 to 10.

The compounds represented by formula (G-1) and formula (G-2) can be exemplified below.

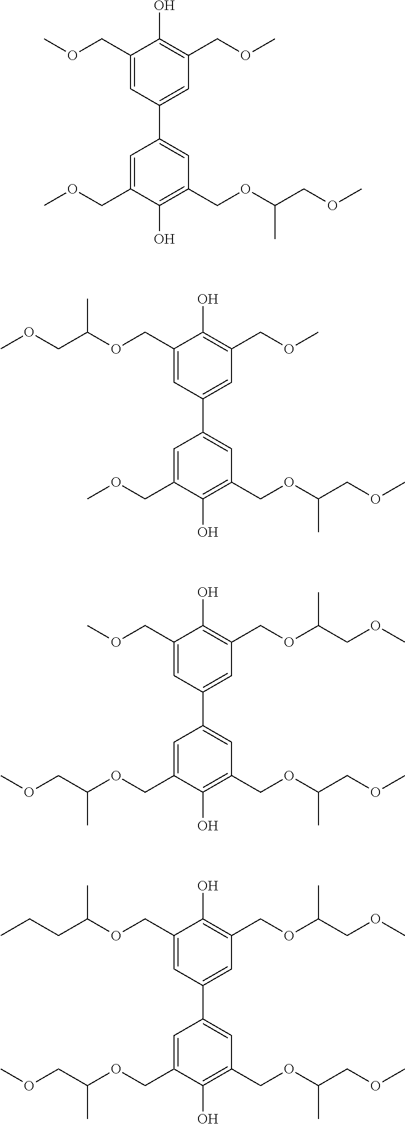

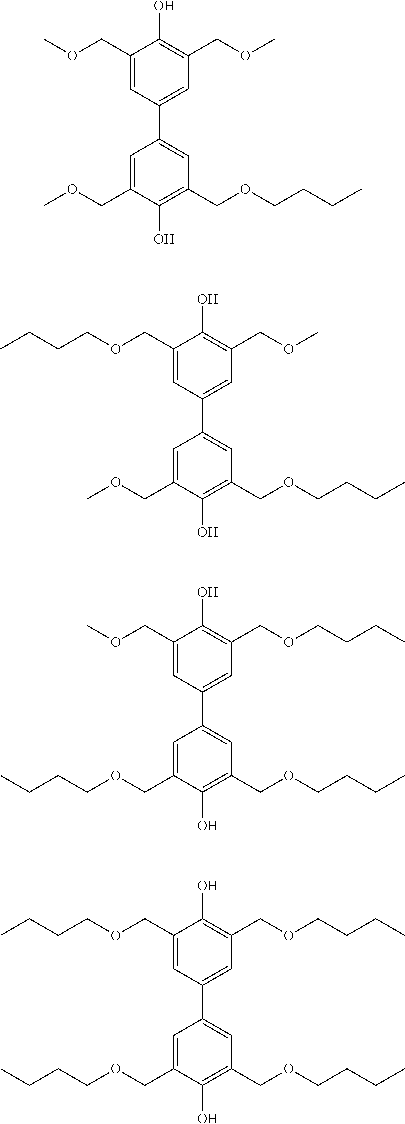

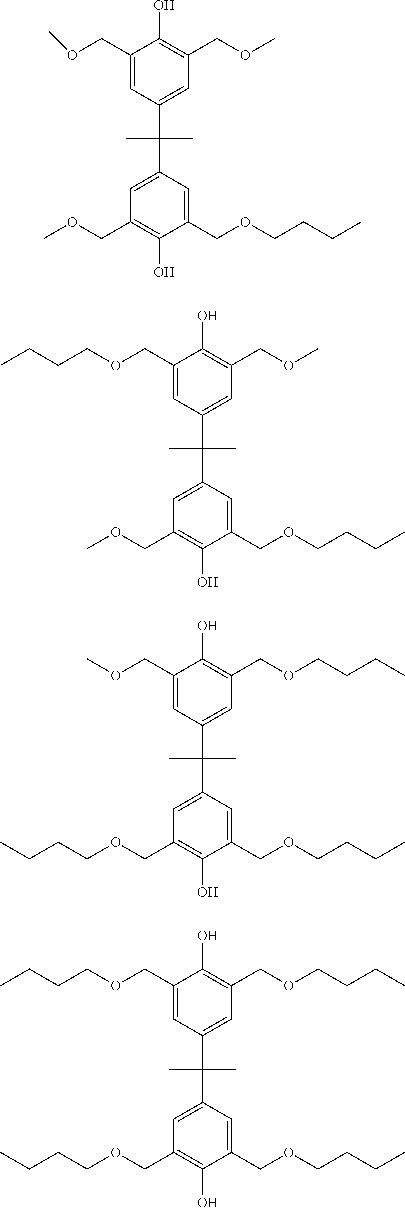

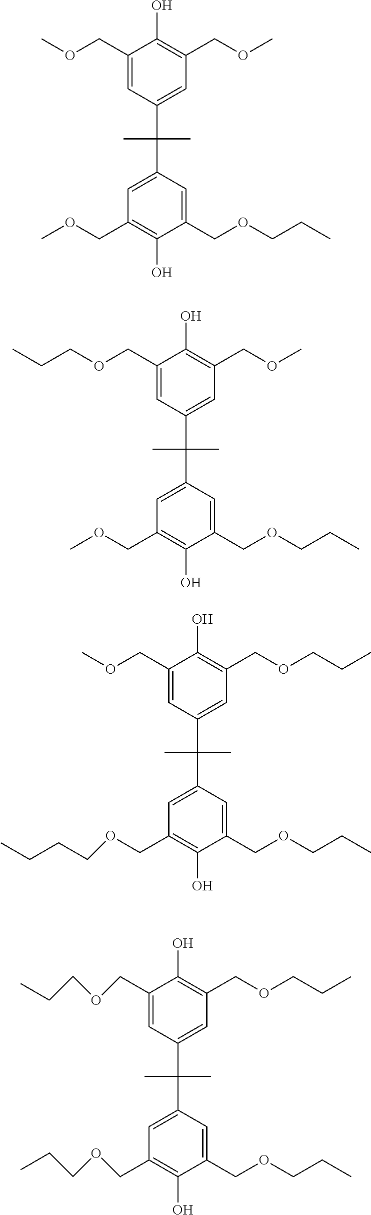

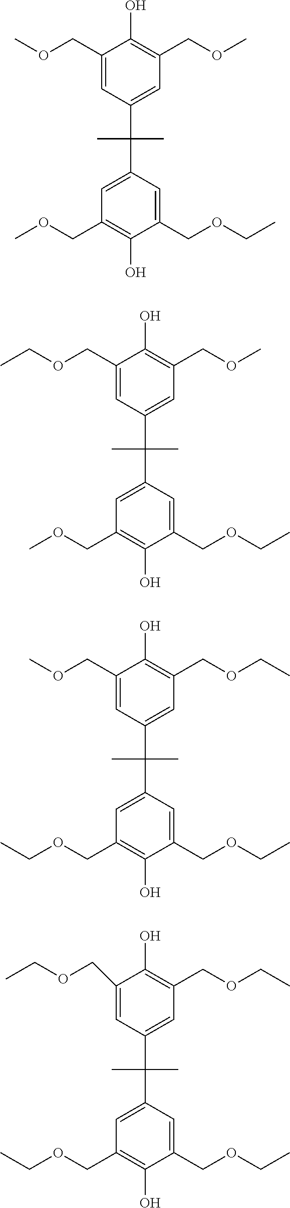

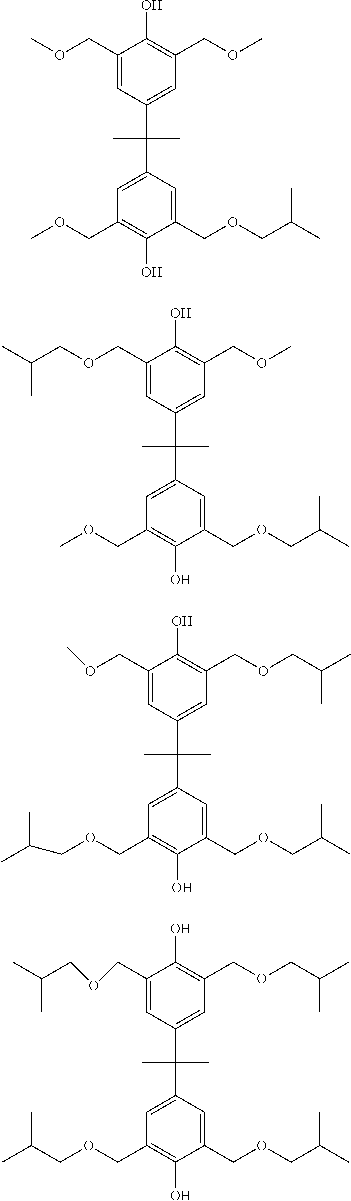

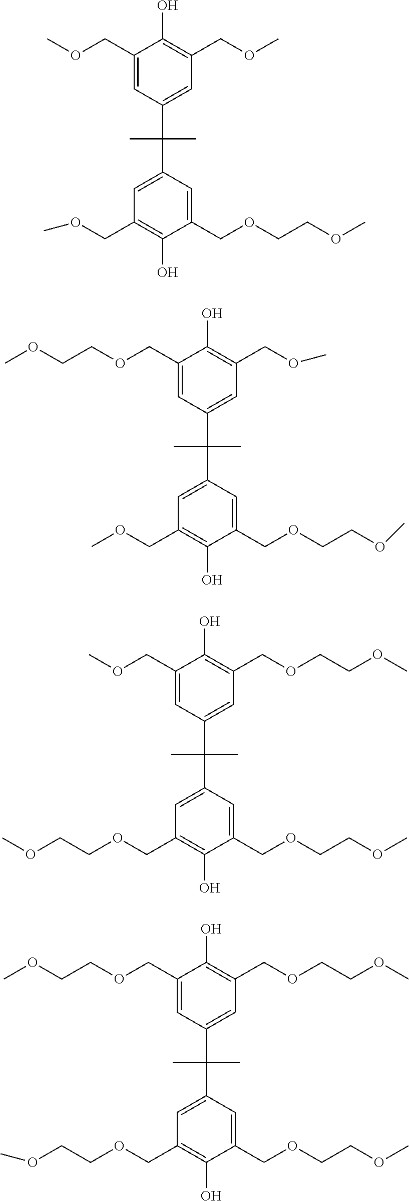

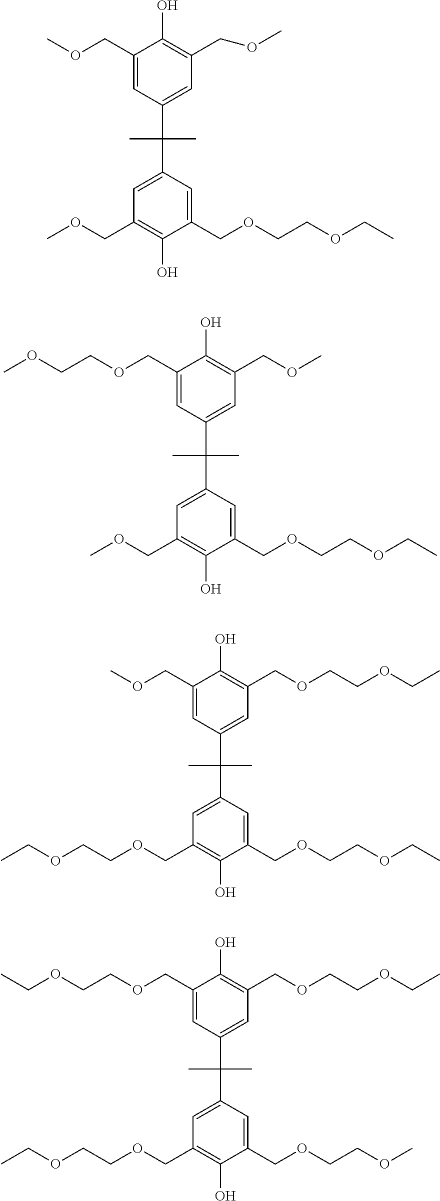

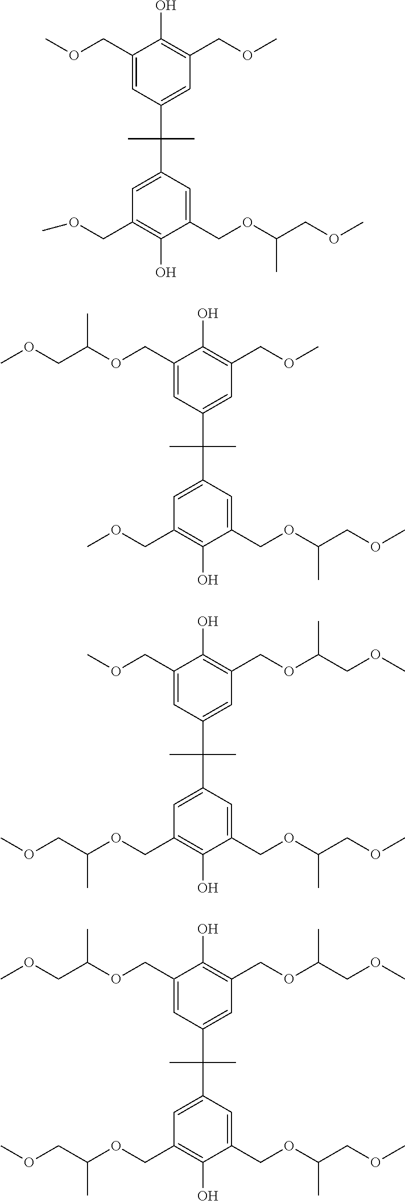

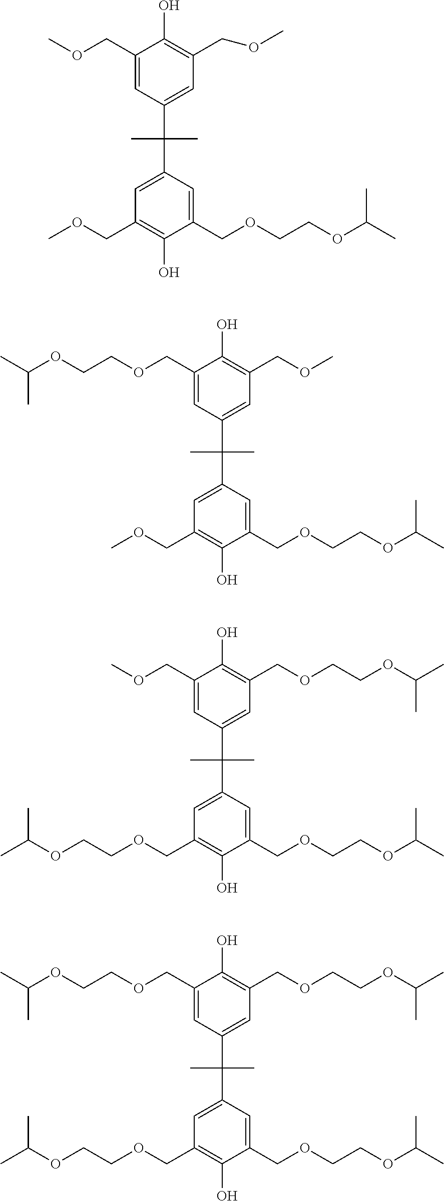

The compounds represented by formula (G-3) and formula (G-4) can be exemplified below.

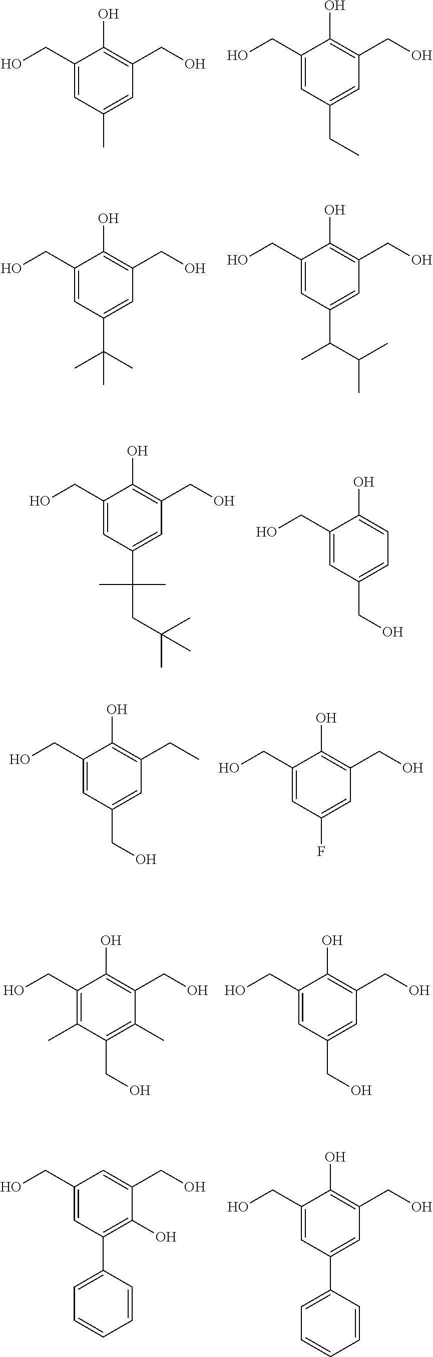

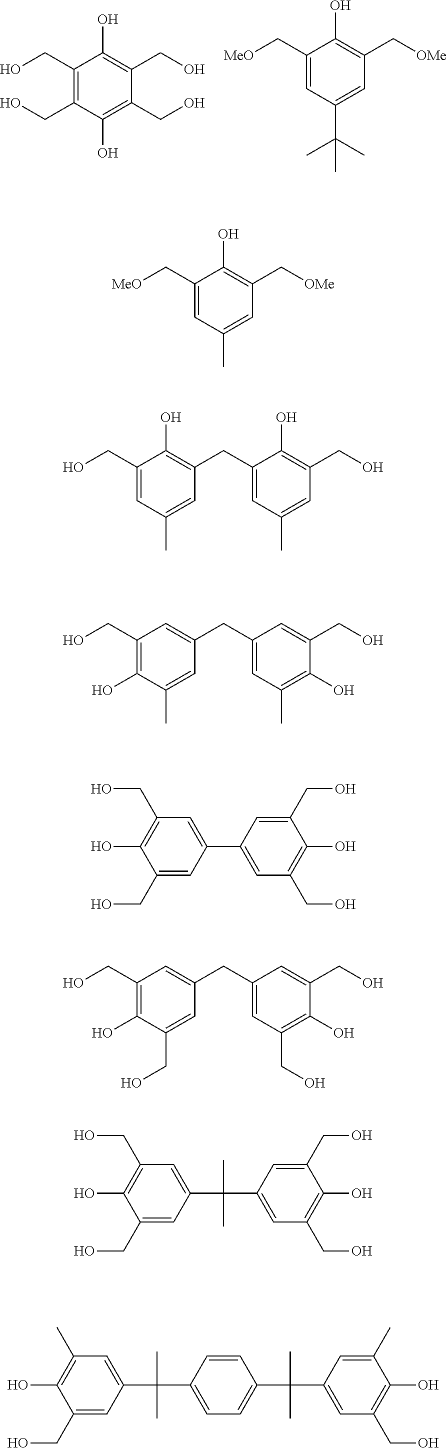

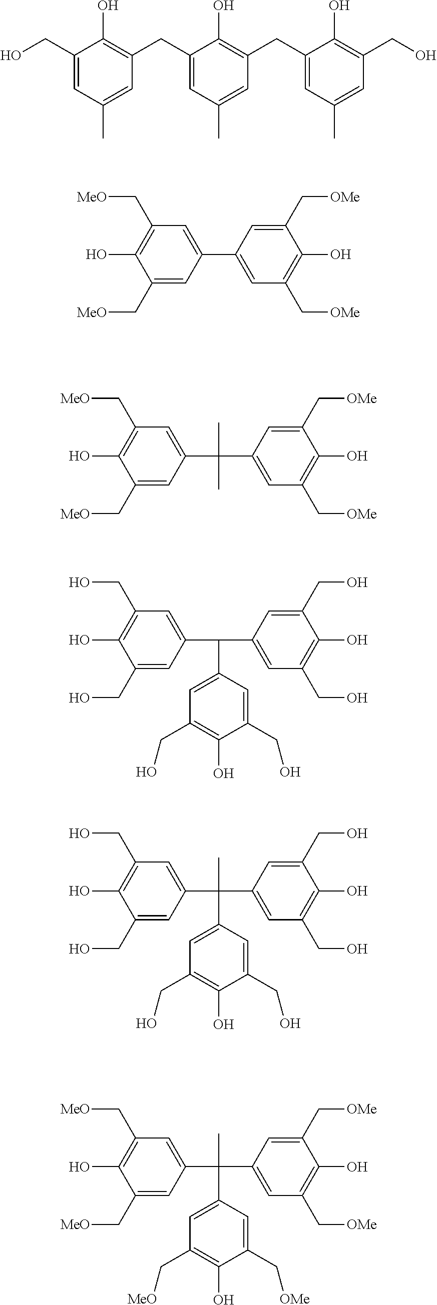

In the formulae, Me represents a methyl group.

The entire disclosure of WO 2014/208542 A is incorporated herein by reference.

When the crosslinking agent is used, the content ratio of the crosslinking agent in the composition for forming a resist underlayer film is, for example, 1 mass % to 50 mass %, preferably 5 mass % to 40 mass % with respect to the polymer containing the structure represented by formula (A).

### <Solvent>

As the solvent, an organic solvent generally used for a chemical solution for a semiconductor lithography process is preferred. Specific examples thereof include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxy cyclopentane, anisole, γ-butyrolactone, N-methylpyrrolidone, N,N-dimethylformamide, and N,N-dimethylacetamide. These solvents can be used alone, or two or more kinds thereof can be used in combination.

Among these solvents, propylene glycol monomethyl ether, propylene glycol monomethyl ether acetate, ethyl lactate, butyl lactate, and cyclohexanone are preferred. In particular, propylene glycol monomethyl ether and propylene glycol monomethyl ether acetate are preferred.

### <Curing Catalyst>

As the curing catalyst contained as an optional component in the composition for forming a resist underlayer film, either of a thermal acid generator and a photoacid generator can be used, but it is preferred to use a thermal acid generator.

Examples of the thermal acid generator include sulfonic acid compounds and carboxylic acid compounds such as p-toluenesulfonic acid, trifluoromethanesulfonic acid, pyridinium p-toluenesulfonate (pyridinium p-toluenesulfonic acid), pyridinium phenolsulfonate, pyridinium p-hydroxybenzenesulfonate (p-phenolsulfonic acid pyridinium salt), pyridinium trifluoromethanesulfonate, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generator include an onium salt compound, a sulfonimide compound, and a disulfonyl diazomethane compound.

Examples of the onium salt compound include iodonium salt compounds such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphorsulfonate, bis(4-tert-butylphenyl)iodonium camphorsulfonate, and bis(4-tert-butylphenyl)iodonium trifluoromethanesulfonate, and sulfonium salt compounds such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Examples of the disulfonyl diazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl p-toluenesulfonyl diazomethane.

Only one kind of curing catalyst can be used, or two or more kinds thereof can be used in combination.

When a curing catalyst is used, the content ratio of the curing catalyst is, for example, 0.1 mass % to 50 mass %, preferably 1 mass % to 30 mass % with respect to the crosslinking agent.

### <Other Components>

In the composition for forming a resist underlayer film, a surfactant can be further added in order to further improve the coating property against surface unevenness without formation of pinholes, striations, or the like.

Examples of the surfactant include nonionic surfactants including polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl allyl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorine-based surfactants such as EFTOP EF301, EF303, and EF352 (trade name, manufactured by Tochem Products Co., Ltd.), MEGAFAC F171, F173, and R-30 (trade name, manufactured by DIC Corporation), Fluorad FC430 and FC431 (trade name, manufactured by Sumitomo 3M Limited), Asahi Guard AG710, Surflon S-382, SC101, SC102, SC103, SC104, SC105, and SC106 (trade name, manufactured by Asahi Glass Co., Ltd.), and an organosiloxane polymer KP341 (manufactured by Shin-Etsu Chemical Co., Ltd.).

The blending amount of such a surfactant is not particularly limited, but is usually 2.0 mass % or less, and preferably 1.0 mass % or less with respect to the total solid content of the composition for forming a resist underlayer film.

These surfactants may be added alone, or two or more kinds thereof may be added in combination.

The film-forming component contained in the composition for forming a resist underlayer film, that is, the component excluding the solvent is, for example, 0.01 mass % to 10 mass % of the composition for forming a resist underlayer film.

The composition for forming a resist underlayer film is preferably used for forming a resist underlayer film for use in EB or EUV lithography having a film thickness of 10 nm or less.

### (Resist Underlayer Film)

The resist underlayer film of the present invention is a cured product of the composition for forming a resist underlayer film described above.

The resist underlayer film can be produced, for example, by applying the composition for forming a resist underlayer film described above onto a semiconductor substrate and baking the composition.

Examples of the semiconductor substrate to which the composition for forming a resist underlayer film is applied include a silicon wafer, a germanium wafer, and a compound semiconductor wafer of gallium arsenide, indium phosphide, gallium nitride, indium nitride, aluminum nitride, or the like.

When a semiconductor substrate having an inorganic film formed on a surface thereof is used, the inorganic film is formed by, for example, an atomic layer deposition (ALD) method, a chemical vapor deposition (CVD) method, a reactive sputtering method, an ion plating method, a vacuum deposition method, or a spin coating method (spin-on glass: SOG). Examples of the inorganic film include a polysilicon film, a silicon oxide film, a silicon nitride film, a boro-phospho silicate glass (BPSG) film, a titanium nitride film, a titanium nitride oxide film, a tungsten film, a gallium nitride film, and a gallium arsenide film.

The composition for forming a resist underlayer film of the present invention is applied onto such a semiconductor substrate by an appropriate application method such as a spinner or a coater. Thereafter, the composition is baked using a heating unit such as a hot plate to form a resist underlayer film. The baking conditions are appropriately selected from the baking temperature of 100° C. to 400° C. and from the baking time of 0.3 minutes to 60 minutes. It is preferred that the baking temperature is 120° C. to 350° C. and the baking time is 0.5 minutes to 30 minutes, and it is more preferred that the baking temperature is 150° C. to 300° C. and the baking time is 0.8 minutes to 10 minutes.

The film thickness of the resist underlayer film is preferably 10 nm or less, more preferably 9 nm or less, still more preferably 8 nm or less, and particularly preferably 7 nm or less from the viewpoint of suitably obtaining the effect of the present invention. The film thickness of the resist underlayer film may be 1 nm or more, or 2 nm or more, or 3 nm or more.

The method of measuring the film thickness of the resist underlayer film in the present description is, for example, as follows.
Measuring device name: ellipsometric film thickness measurement system RE-3100 (SCREEN Semiconductor Solutions Co., Ltd.)
Single wavelength ellipsometer (SWE) mode
Arithmetic average of measurements at 8 points (for example, measurement is made at 8 points at intervals of 1 cm in X direction of wafer)

### (Substrate for Semiconductor Processing)

The substrate for semiconductor processing of the present invention includes a semiconductor substrate and the resist underlayer film of the present invention.

Examples of the semiconductor substrate include semiconductor substrates described above.

The resist underlayer film is disposed, for example, on the semiconductor substrate.

### (Method for Producing Semiconductor Element, and Method for Forming Pattern)

The method for producing a semiconductor element of the present invention includes at least the following steps.
a step of forming a resist underlayer film on a semiconductor substrate using the composition for forming a resist underlayer film of the present invention, and
a step of forming a resist film on the resist underlayer film using a resist

The method for forming a pattern of the present invention includes at least the following steps.
a step of forming a resist underlayer film on a semiconductor substrate using the composition for forming a resist underlayer film of the present invention,
a step of forming a resist film on the resist underlayer film using a resist
a step of irradiating the resist film with light or an electron beam, and then developing the resist film to obtain a resist pattern, and
a step of etching the resist underlayer film using the resist pattern as a mask

Usually, a resist film is formed on the resist underlayer film.

The film thickness of the resist film is preferably 200 nm or less, more preferably 150 nm or less, still more preferably 100 nm or less, and particularly preferably 80 nm or less. Further, the film thickness of the resist film is preferably 10 nm or more, more preferably 20 nm or more, and particularly preferably 30 nm or more.

A resist formed on the resist underlayer film by application and baking using a known method is not particularly limited as long as the resist responds to light or an electron beam used for irradiation. Both a negative photoresist and a positive photoresist can be used.

In the present description, a resist responding to an electron beam (EB) is also referred to as a photoresist.

Examples of the photoresist include a positive photoresist made of a novolak resin and 1,2-naphthoquinonediazide sulfonic acid ester, a chemically amplified photoresist made of a binder having a group, which is decomposed by an acid to increase the alkali dissolution rate, and a photoacid generator, a chemically amplified photoresist made of a low molecular compound, which is decomposed by an acid to increase the alkali dissolution rate of the photoresist, an alkali-soluble binder, and a photoacid generator, a chemically amplified photoresist made of a binder having a group, which is decomposed by an acid to increase the alkali dissolution rate, a low molecular compound, which is decomposed by an acid to increase the alkali dissolution rate of the photoresist, and a photoacid generator, and a resist containing a metal element. Examples thereof include V146G (trade name) manufactured by JSR Corporation, APEX-E (trade name) manufactured by Shipley Company, Inc., PAR710 (trade name) manufactured by Sumitomo Chemical Co., Ltd., and AR2772 and SEPR430 (trade names) manufactured by Shin-Etsu Chemical Co., Ltd. Further, examples thereof include fluorine atom-containing polymer-based photoresists as described in Proc. SPIE, Vol. 3999, 330-334 (2000), Proc. SPIE, Vol. 3999, 357-364 (2000), and Proc. SPIE, Vol. 3999, 365-374 (2000).

Further, a resist composition, a radiation-sensitive resin composition, a so-called resist composition such as a high-resolution patterning composition based on an organometallic solution, and a metal-containing resist composition described in the following documents can be used, but not limited thereto: WO 2019/188595 A, WO 2019/187881 A, WO 2019/187803 A, WO 2019/167737 A, WO 2019/167725 A, WO 2019/187445 A, WO 2019/167419 A, WO 2019/123842 A, WO 2019/054282 A, WO 2019/058945 A, WO 2019/058890 A, WO 2019/039290 A, WO 2019/044259 A, WO 2019/044231 A, WO 2019/026549 A, WO 2018/193954 A, WO 2019/172054 A, WO 2019/021975 A, WO 2018/230334 A, WO 2018/194123 A, JP 2018-180525 A, WO 2018/190088 A, JP 2018-070596 A, JP 2018-028090 A, JP 2016-153409 A, JP 2016-130240 A, JP 2016-108325 A, JP 2016-047920 A, JP 2016-035570 A, JP 2016-035567 A, JP 2016-035565 A, JP 2019-101417 A, JP 2019-117373 A, JP 2019-052294 A, JP 2019-008280 A, JP 2019-008279 A, JP 2019-003176 A, JP 2019-003175 A, JP 2018-197853 A, JP 2019-191298 A, JP 2019-061217 A, JP 2018-045152 A, JP 2018-022039 A, JP 2016-090441 A, JP 2015-10878 A, JP 2012-168279 A, JP 2012-022261 A, JP 2012-022258 A, JP 2011-043749 A, JP 2010-181857 A, JP 2010-128369 A, WO 2018/031896 A, JP 2019-113855 A, WO 2017/156388 A, WO 2017/066319 A, JP 2018-41099 A, WO 2016/065120 A, WO 2015/026482 A, JP 2016-29498 A, and JP 2011-253185 A.

Examples of the resist composition include the following compositions.

An active light-sensitive or radiation-sensitive resin composition that contains a resin A including a repeating unit having an acid decomposable group in which a polar group is protected by a protecting group to be removed by the action of an acid, and that contains a compound represented by general formula (21) below.

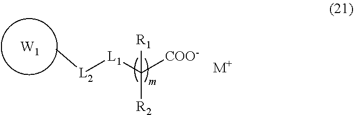

In general formula (21), m represents an integer of 1 to 6.
R₁ and R₂ each independently represent a fluorine atom or a perfluoroalkyl group.
L₁ represents —O—, —S—, —COO—, —SO₂—, or —SO₃—.
L₂ represents an alkylene group which may have a substituent or a single bond.
W₁ represents a cyclic organic group which may have a substituent.
M⁺ represents a cation.

A metal-containing film-forming composition for use in extreme ultraviolet light or electron beam lithography, which contains a compound having a metal-oxygen covalent bond, and a solvent, and in which a metal element constituting the compound belongs to periods 3 to 7 of groups 3 to 15 of the periodic table.

A radiation-sensitive resin composition that contains a polymer having a first structural unit represented by formula (31) below and a second structural unit represented by formula (32) below and containing an acid-dissociable group, and that contains an acid generator.

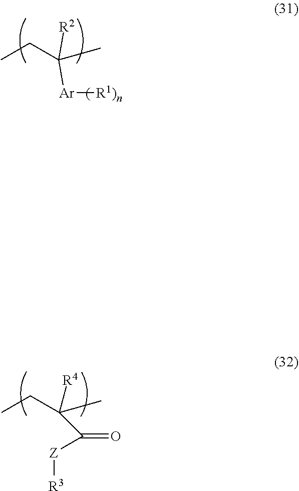

In formula (31), Ar is a group obtained by removing (n+1) hydrogen atoms from an arene having 6 to 20 carbon atoms, R¹ is a hydroxy group, a sulfanyl group, or a monovalent organic group having 1 to 20 carbon atoms, n is an integer of 0 to 11, when n is 2 or more, a plurality of R¹'s are identical or different, and R² is a hydrogen atom, a fluorine atom, a methyl group, or a trifluoromethyl group. In formula (32), R³ is a monovalent group having 1 to 20 carbon atoms and containing the acid-dissociable group, Z is a single bond, an oxygen atom, or a sulfur atom, and R⁴ is a hydrogen atom, a fluorine atom, a methyl group, or a trifluoromethyl group.

A resist composition that contains a resin (A1) including a structural unit having a cyclic carbonate structure, a structural unit represented by a formula below, and a structural unit having an acid-unstable group, and that contains an acid generator.

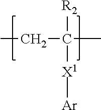

In the formula,
R² represents an alkyl group having 1 to 6 carbon atoms, which may have a halogen atom, a hydrogen atom, or a halogen atom, X¹ represents a single bond, —CO—O—*, or —CO—NR⁴—* where * represents a bond with —Ar, R⁴ represents a hydrogen atom or an alkyl group having 1 to 4 carbon atoms, and Ar represents an aromatic hydrocarbon group having 6 to 20 carbon atoms, which may have one or more groups selected from the group consisting of a hydroxy group and a carboxyl group.

Examples of the resist film include the following.

A resist film containing a base resin including a repeating unit represented by formula (a1) below and/or a repeating unit represented by formula (a2) below, and a repeating unit which generates an acid bonded to a polymer main chain by exposure.

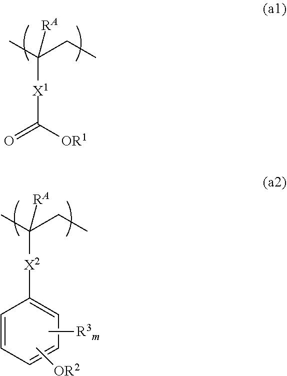

In formula (a1) and formula (a2), R^{A}'s are each independently a hydrogen atom or a methyl group, R¹ and R² are each independently a tertiary alkyl group having 4 to 6 carbon atoms, R³'s are each independently a fluorine atom or a methyl group, m is an integer of 0 to 4, X¹ is a single bond, a phenylene group, or a naphthylene group, or a linking group having 1 to 12 carbon atoms containing at least one selected from an ester bond, a lactone ring, a phenylene group, and a naphthylene group, and X² is a single bond, an ester bond, or an amide bond.

Examples of a resist material include the following.

A resist material containing a polymer having a repeating unit represented by formula (b1) or formula (b2) below.

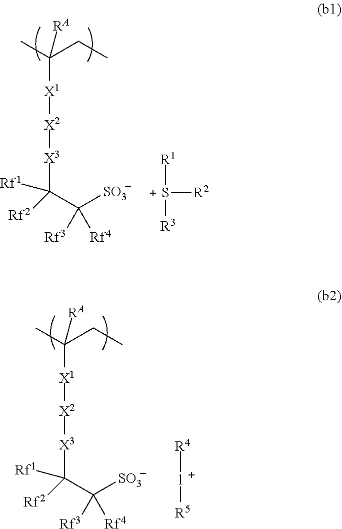

In formula (b1) and formula (b2), R^{A} is a hydrogen atom or a methyl group, X¹ is a single bond or an ester group, X² is a linear, branched, or cyclic alkylene group having 1 to 12 carbon atoms or an arylene group having 6 to 10 carbon atoms, and a methylene group constituting the alkylene group may be partially substituted by an ether group, an ester group, or a lactone ring-containing group, and at least one hydrogen atom contained in X² is substituted by a bromine atom, X³ is a single bond, an ether group, an ester group, or a linear, branched, or cyclic alkylene group having 1 to 12 carbon atoms, and a methylene group constituting the alkylene group may be partially substituted by an ether group or an ester group, Rf¹ to Rf⁴ are each independently a hydrogen atom, a fluorine atom, or a trifluoromethyl group, at least one of Rf¹ to Rf⁴ is a fluorine atom or a trifluoromethyl group, and Rf¹ and Rf² may be combined to form a carbonyl group, R¹ to R⁵ are each independently a linear, branched, or cyclic alkyl group having 1 to 12 carbon atoms, a linear, branched, or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, and some or all of hydrogen atoms of these groups may be substituted by a hydroxy group, a carboxy group, a halogen atom, an oxo group, a cyano group, an amide group, a nitro group, a sultone group, a sulfone group, or a sulfonium salt-containing group, and methylene groups constituting these groups may be partially substituted by an ether group, an ester group, a carbonyl group, a carbonate group, or a sulfonic acid ester group, and R¹ and R² may be bonded to form a ring together with the sulfur atom to which R¹ and R² are bonded.

A resist material containing a base resin containing a polymer including a repeating unit represented by formula (a) below.

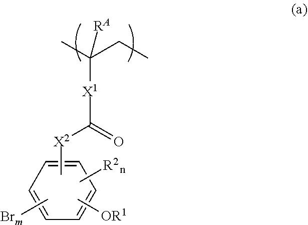

In formula (a), R^{A} is a hydrogen atom or a methyl group, R¹ is a hydrogen atom or an acid-unstable group, R² is a linear, branched, or cyclic alkyl group having 1 to 6 carbon atoms or a halogen atom other than bromine, X¹ is a single bond or a phenylene group, or a linear, branched, or cyclic alkylene group having 1 to 12 carbon atoms which may contain an ester group or a lactone ring, X² is —O—, —O—CH₂—, or —NH—, m is an integer of 1 to 4, and u is an integer of 0 to 3, however, m+u is an integer of 1 to 4.

A resist composition, which generates an acid by exposure and changes its solubility in a developer by the action of an acid, and contains
a base material component (A) that changes its solubility in a developer by the action of an acid, and a fluorine additive component (F) that exhibits decomposability against an alkaline developer, and in which
the fluorine additive component (F) contains a fluororesin component (F1) having a constituent unit (f1) containing a base-dissociable group and a constituent unit (f2) containing a group represented by general formula (f2-r-1) below.

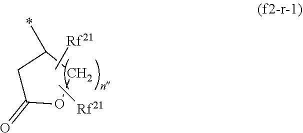

In formula (f2-r-1), Rf²¹'s are each independently a hydrogen atom, an alkyl group, an alkoxy group, a hydroxy group, a hydroxyalkyl group, or a cyano group, n″ is an integer of 0 to 2, and * is a bond.

The constituent unit (f1) includes a constituent unit represented by general formula (f1-1) below or a constituent unit represented by general formula (f1-2) below.

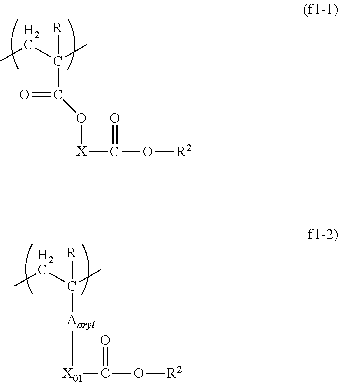

In formulae (f1-1) and (f1-2), R's are each independently a hydrogen atom, an alkyl group having 1 to 5 carbon atoms, or a halogenated alkyl group having 1 to 5 carbon atoms, X is a divalent linking group having no acid-dissociable site, A_{aryl} is a divalent aromatic cyclic group which may have a substituent, X₀₁ is a single bond or a divalent linking group, and R²'s are each independently an organic group having a fluorine atom.

Examples of a coating, a coating solution, and a coating composition include the following.

A coating containing a metal oxo-hydroxo network having an organic ligand through a metal-carbon bond and/or a metal-carboxylate bond.

An inorganic oxo/hydroxo-based composition.

A coating solution containing an organic solvent; a first organometallic composition represented by a formula R_{z}SnO_{(2-(z/2)-(x/2)})(OH)ₓ (where 0<z≤2 and 0<(z+x)≤4), a formula R′ₙSnX₄₋ₙ (where n=1 or 2), or a mixture thereof, wherein R and R′ are independently a hydrocarbyl group having 1 to 31 carbon atoms, and X is a ligand having a hydrolysable bond to Sn or a combination thereof; and a hydrolysable metal compound represented by a formula MX′ᵥ (where M is a metal selected from groups 2 to 16 of the periodic table of elements, v=a number of 2 to 6, and X′ is a ligand having a hydrolysable M-X bond or a combination thereof).

A coating solution containing an organic solvent and a first organometallic compound represented by a formula RSnO_{(3/2-x/2)}(OH)ₓ (where 0<x<3), wherein the solution contains about 0.0025 M to about 1.5 M of tin and R is an alkyl group or a cycloalkyl group having 3 to 31 carbon atoms and the alkyl group or the cycloalkyl group is bonded to tin at a secondary or tertiary carbon atom.

An inorganic pattern forming precursor aqueous solution containing a mixture of water, a metal suboxide cation, a polyatomic inorganic anion, and a radiation-sensitive ligand containing a peroxide group.

The irradiation with light or an electron beam is performed, for example, through a mask (reticle) for forming a predetermined pattern. The composition for forming a resist underlayer film of the present invention is preferably applied for irradiation with an electron beam (EB) or extreme ultraviolet (EUV: 13.5 nm), but is more preferably applied for exposure to extreme ultraviolet (EUV).

The irradiation energy of EB and the exposure amount of EUV are not particularly limited.

Bake (post exposure bake: PEB) may be performed after irradiation with light or an electron beam and before development.

The baking temperature is not particularly limited, but is preferably 60° C. to 150° C., more preferably 70° C. to 120° C., and particularly preferably 75° C. to 110° C.

The baking time is not particularly limited, but is preferably 1 second to 10 minutes, more preferably 10 seconds to 5 minutes, and particularly preferably 30 seconds to 3 minutes.

In the development, for example, an alkaline developer is used.

Examples of the development temperature include 5° C. to 50° C.

Examples of the developing time include 10 seconds to 300 seconds.

As the alkaline developer, for example, an aqueous solution of an inorganic alkali such as sodium hydroxide, potassium hydroxide, sodium carbonate, sodium silicate, sodium metasilicate, or aqueous ammonia, a primary amine such as ethylamine or n-propylamine, a secondary amine such as diethylamine or di-n-butylamine, a tertiary amine such as triethylamine or methyldiethylamine, an alcohol amine such as dimethylethanolamine or triethanolamine, a quaternary ammonium salt such as tetramethylammonium hydroxide, tetraethylammonium hydroxide, or choline, or a cyclic amine such as pyrrole or piperidine can be used. Further, the aqueous solution of an alkali can also be used by adding an appropriate amount of an alcohol such as isopropyl alcohol or a surfactant such as a nonionic surfactant thereto. Among these, a preferred developer is an aqueous solution of a quaternary ammonium salt, and more preferred developers are an aqueous solution of tetramethylammonium hydroxide and an aqueous solution of choline. Further, a surfactant or the like can also be added to these developers. It is also possible to use a method in which development is performed with an organic solvent such as butyl acetate in place of the alkaline developer and a portion where the alkali dissolution rate of the photoresist is not improved is developed.

Subsequently, the resist underlayer film is etched using the formed resist pattern as a mask. The etching may be dry etching or wet etching, but is preferably dry etching.

When the inorganic film is formed on the surface of a semiconductor substrate used, the surface of the inorganic film is exposed, and when the inorganic film is not formed on the surface of a semiconductor substrate used, the surface of the semiconductor substrate is exposed. Thereafter, the semiconductor substrate is subjected to a step of processing the semiconductor substrate by a known method (a dry etching method or the like), whereby a semiconductor device can be produced.

### EXAMPLES

Next, the contents of the present invention will be specifically described with reference to examples, but the present invention is not limited thereto.

The weight average molecular weight of each of the polymers shown in the following Synthesis Example 1 and Comparative Synthesis Example 1 is a measurement result by gel permeation chromatography (hereinafter abbreviated as GPC). In the measurement, a GPC apparatus manufactured by Tosoh Corporation was used, and measurement conditions and the like are as follows.
GPC column: Shodex KF803L, Shodex KF802, Shodex KF801 [registered trademark](Showa Denko K.K.)
Column temperature: 40° C.
Solvent: N,N-dimethylformamide (DMF)
Flow rate: 0.6 ml/min
Standard sample: polystyrene (manufactured by Tosoh Corporation)

### Synthesis Example 1

To 23.34 g of propylene glycol monomethyl ether in a reaction vessel, 3.00 g of a novolac-type epoxy resin EOCN-104S (manufactured by Nippon Kayaku Co., Ltd.), 2.66 g of o-sulfobenzimide (manufactured by Tokyo Chemical Industry Co., Ltd.), and 0.18 g of tetrabutylphosphonium bromide (manufactured by Tokyo Chemical Industry Co., Ltd.) were added and dissolved therein. The reaction vessel was purged with nitrogen, and then, a reaction was allowed to proceed at 120° C. for 24 hours to obtain a polymer solution. As a result of GPC analysis, Polymer 1 obtained had a weight average molecular weight of 6,500 in terms of standard polystyrene and a dispersity of 3.0. The structure present in Polymer 1 is represented by a formula below.

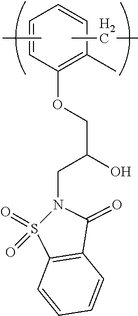

### Comparative Synthesis Example 1

To 24.38 g of propylene glycol monomethyl ether in a reaction vessel, 3.00 g of a novolac-type epoxy resin EOCN-104S (manufactured by Nippon Kayaku Co., Ltd.), 2.92 g of 4-methylsulfonylbenzoic acid (manufactured by Tokyo Chemical Industry Co., Ltd.), and 0.18 g of tetrabutylphosphonium bromide (manufactured by Tokyo Chemical Industry Co., Ltd.) were added and dissolved therein. The reaction vessel was purged with nitrogen, and then, a reaction was allowed to proceed at 120° C. for 24 hours to obtain a polymer solution. As a result of GPC analysis, Polymer 2 obtained had a weight average molecular weight of 8,700 in terms of standard polystyrene and a dispersity of 3.1. The structure present in Polymer 2 is represented by a formula below.

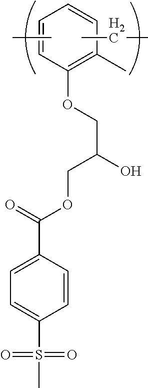

### (Preparation of Resist Underlayer Film)

### EXAMPLES

The polymer obtained in Synthesis Example 1 or Comparative Synthesis Example 1, a crosslinking agent, a curing catalyst, and a solvent were mixed in the proportions shown in Table 1, and the mixture was filtered through a 0.1 μm fluororesin filter to prepare each composition for forming a resist underlayer film.

Abbreviations in Table 1 are as follows.
PL-LI: tetramethoxymethyl glycoluril (manufactured by Nihon Cytec Industries Inc.)
PGME-PL: Imidazo[4,5-d]imidazole-2,5(1H,3H)-dione, tetrahydro-1,3,4,6-tetrakis[(2-methoxy-1-methylethoxy)methyl]-(structural formula below)

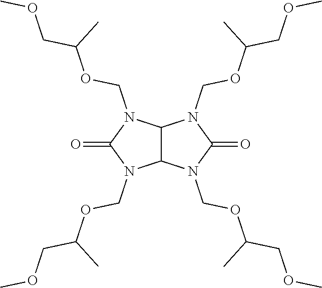

PyPSA: pyridinium p-hydroxybenzenesulfonate
PGMEA: propylene glycol monomethyl ether acetate
PGME: propylene glycol monomethyl ether

TABLE 1

| | | Crosslinking | Curing | | |
|---|---|---|---|---|---|
| | Polymer | agent | catalyst | Solvent | |
| Example 1 | Synthesis | PGME-PL | PyPSA | PGME | PGMEA |
| | Example 1 | | | | |
| (parts by | 0.15 | 0.04 | 0.01 | 10 | 90 |
| mass) | | | | | |
| Example 2 | Synthesis | PL-LI | PyPSA | PGME | PGMEA |
| | Example 1 | | | | |
| (parts by | 0.15 | 0.04 | 0.01 | 10 | 90 |
| mass) | | | | | |
| Comparative | Comparative | PGME-PL | PyPSA | PGME | PGMEA |
| Example 1 | Synthesis | | | | |
| | Example 1 | | | | |
| (parts by | 0.15 | 0.04 | 0.01 | 10 | 90 |
| mass) | | | | | |
| Comparative | Comparative | PL-LI | PyPSA | PGME | PGMEA |
| Example 2 | Synthesis | | | | |
| | Example 1 | | | | |
| (parts by | 0.15 | 0.04 | 0.01 | 10 | 90 |
| mass) | | | | | |

### (Elution Test in Photoresist Solvent)

Each of the compositions for forming a resist underlayer film of Example 1 and Comparative Example 1 was applied onto a silicon wafer using a spinner. The silicon wafer was baked at 205° C. for 60 seconds on a hot plate to obtain a resist underlayer film having a film thickness of 5 nm. These resist underlayer films were immersed in a mixed solution of propylene glycol monomethyl ether/propylene glycol monomethyl ether acetate=70/30 (mass ratio), which is a solvent used for the photoresist, and a case where the film thickness change was less than 1 A was evaluated as “good”, and a case where the film thickness change was 1 A or more was evaluated as “poor”, and the results are shown in Table 2.

### (Film Formability Test)

Each of the compositions for forming a resist underlayer film of Example 1 and Comparative Example 1 was applied onto a silicon wafer using a spinner. The silicon wafer was baked at 205° C. for 60 seconds on a hot plate to obtain a resist underlayer film having a film thickness of 5 nm. The surface roughness (Sa) of these resist underlayer films was measured using an atomic force microscope (AFM). A case where the surface roughness (Sa) was less than 3 Å was evaluated as “good”, and a case where the surface roughness (Sa) was 3 A or more was evaluated as “poor”, and the results are shown in Table 2.

TABLE 2

| | Elution test | Coating property |
|---|---|---|
| Example 1 | Good | Good |
| Comparative | Good | Good |
| Example 1 | | |

### (Evaluation of Resist Patterning)

### [Test of Resist Pattern Formation by Electron Beam Lithography System]

Each of the compositions for forming a resist underlayer film of Example 1 and Comparative Example 1 was applied onto a silicon wafer using a spinner. The silicon wafer was baked at 205° C. for 60 seconds on a hot plate to obtain a resist underlayer film having a film thickness of 5 nm. A positive resist solution for EUV was spin-coated on the resist underlayer film, followed by heating to 110° C. for 60 seconds to form an EUV resist film. The resist film was irradiated with EB under predetermined conditions using an electron beam lithography system (ELS-G130). After irradiation, bake (PEB) was performed at 90° C. for 60 seconds and cooled to room temperature on a cooling plate, and paddle development was performed for 60 seconds using a 2.38% aqueous tetramethylammonium hydroxide solution (trade name NMD-3 manufactured by TOKYO OHKA KOGYO CO., LTD.) as a photoresist developer. A resist pattern having a line size of 15 nm to 27 nm was formed. A scanning electron microscope (CG4100 manufactured by Hitachi High-Technologies Corporation) was used for measuring the length of the resist pattern.

With respect to the photoresist pattern thus obtained, whether or not a 22 nm line-and-space (L/S) could be formed was evaluated. In both Example 1 and Comparative Example 1, 22 nm L/S pattern formation was observed. In addition, the amount of charge with which the 22 nm line/44 nm pitch (line-and-space (L/S=1/1) was formed is defined as the optimal irradiation energy, and shown in Table 2. The smaller the value of the optimal irradiation energy (μC/cm²) at that time is, the higher the sensitivity of the resist is. However, the result of Example 1 shows an equivalent value to that of Comparative Example 1, indicating that there is no difference in sensitivity. In addition, observation was performed from the top of the pattern, and the minimum critical dimension (CD) size at which no collapse of the resist pattern in the shot was observed was checked. The smaller this value is, the better the adhesion to the resist is, and in the result of Example 1, the value of the minimum CD size is smaller than that of Comparative Example 1, and better adhesion to the resist is exhibited.

TABLE 3

| | Optimal irradiation energy | Minimum CD size |
|---|---|---|
| | (μc/cm²) | (nm) |
| Example 1 | 430 | 18 |
| Comparative | 430 | 20 |
| Example 1 | | |

1. A composition for forming a resist underlayer film, comprising a solvent and a polymer including a structure represented by formula (A) below: 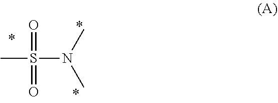
in formula (A), * represents a bond.

2. The composition for forming a resist underlayer film according to claim 1, wherein the polymer has a structure represented by formula (A) in a side chain.

3. The composition for forming a resist underlayer film according to claim 1, wherein the polymer has a structure represented by formula (A) in a unit structure.

4. The composition for forming a resist underlayer film according to claim 1, wherein the polymer has, in a side chain, a structure represented by formula (A-1) below as a structure including the structure represented by formula (A): 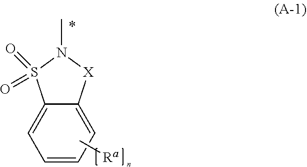
in formula (A-1), X represents —CO— or —SO₂—,
R^{a} represents a halogen atom, an alkyl group having 1 to 8 carbon atoms, which may have a substituent, an alkoxy group having 1 to 8 carbon atoms, which may have a substituent, an alkylthio group having 1 to 5 carbon atoms, a nitro group, or a cyano group,
n represents an integer of 0 to 4,
when there are two or more R^{a}'s, two or more R^{a}'s may be identical or different, and
* represents a bond.

5. The composition for forming a resist underlayer film according to claim 4, wherein the polymer has a unit structure represented by formula (1) below as a unit structure including the structure represented by formula (A-1): 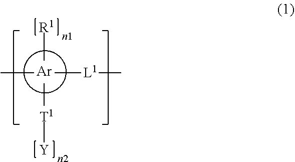
in formula (1), Ar represents a benzene ring, a naphthalene ring, or an anthracene ring,
R¹ represents a hydroxy group, a mercapto group which may be protected by a methyl group, an amino group which may be protected by a methyl group, a halogen atom, or an alkyl group having 1 to 10 carbon atoms, which may be substituted or interrupted by a hetero atom or may be substituted by a hydroxy group,
n1 represents an integer of 0 to 3,
n2 represents 1 or 2,
L¹ represents a single bond or an alkylene group having 1 to 10 carbon atoms,
Y represents a group represented by formula (A-2) below,
T¹ represents a single bond, an ether bond, an ester bond, or an amide bond (—NHCO—) when n2 is 1,
T¹ represents a nitrogen atom or an amide bond when n2 is 2, 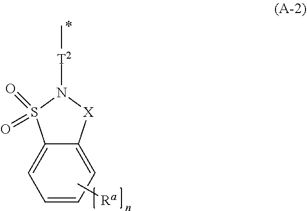
in formula (A-2), T² represents a divalent organic group having 1 to 10 carbon atoms,
X represents —CO— or —SO₂—,
R^{a} represents a halogen atom, an alkyl group having 1 to 8 carbon atoms, which may have a substituent, an alkoxy group having 1 to 8 carbon atoms, which may have a substituent, an alkylthio group having 1 to 5 carbon atoms, a nitro group, or a cyano group,
n represents an integer of 0 to 4,
when there are two or more R^{a}'s, two or more R^{a}'s may be identical or different, and
* represents a bond.

6. The composition for forming a resist underlayer film according to claim 1, further comprising a crosslinking agent.

7. The composition for forming a resist underlayer film according to claim 1, further comprising a curing catalyst.

8. A resist underlayer film which is a cured product of the composition for forming a resist underlayer film according to claim 1.

9. A substrate for semiconductor processing comprising:
a semiconductor substrate; and
the resist underlayer film according to claim 8.

10. A method for producing a semiconductor element, the method comprising steps of:
forming a resist underlayer film using the composition for forming a resist underlayer film according to claim 1; and
forming a resist film on the resist underlayer film using a resist.

11. A method for forming a pattern, the method comprising steps of:
forming a resist underlayer film using the composition for forming a resist underlayer film according to claim 1;
forming a resist film on the resist underlayer film using a resist;
irradiating the resist film with light or an electron beam, and then developing the resist film to obtain a resist pattern; and
etching the resist underlayer film using the resist pattern as a mask.

12. A polymer having a unit structure represented by formula (1) below: 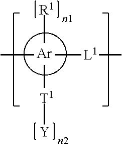
in formula (1), Ar represents a benzene ring, a naphthalene ring, or an anthracene ring,
R¹ represents a hydroxy group, a mercapto group which may be protected by a methyl group, an amino group which may be protected by a methyl group, a halogen atom, or an alkyl group having 1 to 10 carbon atoms, which may be substituted or interrupted by a hetero atom or may be substituted by a hydroxy group,
n1 represents an integer of 0 to 3,
n2 represents 1 or 2,
L¹ represents a single bond or an alkylene group having 1 to 10 carbon atoms,
Y represents a group represented by formula (A-2) below,
T¹ represents a single bond, an ether bond, an ester bond, or an amide bond (—NHCO—) when n2 is 1,
T¹ represents a nitrogen atom or an amide bond when n2 is 2, 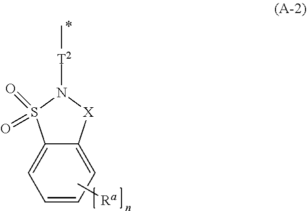
in formula (A-2), T² represents a divalent organic group having 1 to 10 carbon atoms,
X represents —CO— or —SO₂—,
R^{a} represents a halogen atom, an alkyl group having 1 to 8 carbon atoms, which may have a substituent, an alkoxy group having 1 to 8 carbon atoms, which may have a substituent, an alkylthio group having 1 to 5 carbon atoms, a nitro group, or a cyano group,
n represents an integer of 0 to 4,
when there are two or more R^{a}'s, two or more R^{a}'s may be identical or different, and
* represents a bond.
